(19) United States
(12) Patent Application Publication
(10) Pub. No.: US 2012/0262869 A1
(43) Pub. Date: Oct. 18, 2012

(54) DISK DRIVE MOUNTING APPARATUS

(75) Inventors: CHI-KUAN SHEN, Tu-Cheng (TW); SHIH-WEN CHIANG, Tu-Cheng (TW); TUNG-CHUN TSAI, Tu-Cheng (TW); PO-YEN HSU, Tu-Cheng (TW)

(73) Assignee: HON HAI PRECISION INDUSTRY CO., LTD., Tu-Cheng (TW)

(21) Appl. No.: 13/363,443

(22) Filed: Feb. 1, 2012

(30) Foreign Application Priority Data
Apr. 18, 2011 (TW) 100113442

(51) Int. Cl. G06F 1/16; H05K 7/14

(52) U.S. Cl. 361/679.22; 248/309.1

(57) ABSTRACT

A disk drive mounting apparatus including a bracket including a maintaining plate and an installing piece extending from the maintaining plate, and a mounting member including a limiting piece substantially parallel to the installing piece. The mounting member is secured to the maintaining plate in a first position or a second position; a distance between the installing piece and the limiting piece in the first position is larger than a distance between the installing piece and the limiting piece in the second position. When the mounting member is in the first position, the installing piece and the limiting piece are adapted to secure a first disk drive therebetween; and when the mounting member is in the second position, the installing piece and the limiting piece are adapted to secure a second disk drive of a size smaller than a size of the first disk drive.

### BACKGROUND

1. Technical Field

The present disclosure relates to mounting apparatuses and particularly to a disk drive mounting apparatus.

2. Description of Related Art

A computer system usually includes a disk drive, such as a hard disk drive, or a CD-ROM drive. The disk drive is installed in a drive bracket. Usually, the drive bracket determines the size of disk drive, therefore securing disk drives of different sizes may be inconvenient for a user.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an assembled, isometric view of an embodiment of a disk drive mounting apparatus.

FIG. 2 is a partially exploded, isometric view of the assembled disk drive mounting apparatus of FIG. 1 with a first disk drive.

FIG. 3 is an exploded, isometric view of the assembled disk drive mounting apparatus and the first disk drive of FIG. 2, but without a cover member.

FIG. 4 is partially exploded, isometric view of the assembled disk drive mounting apparatus of FIG. 1 with a second disk drive.

FIG. 5 is partially assembled, isometric view of the assembled disk drive mounting apparatus and the second disk drive of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

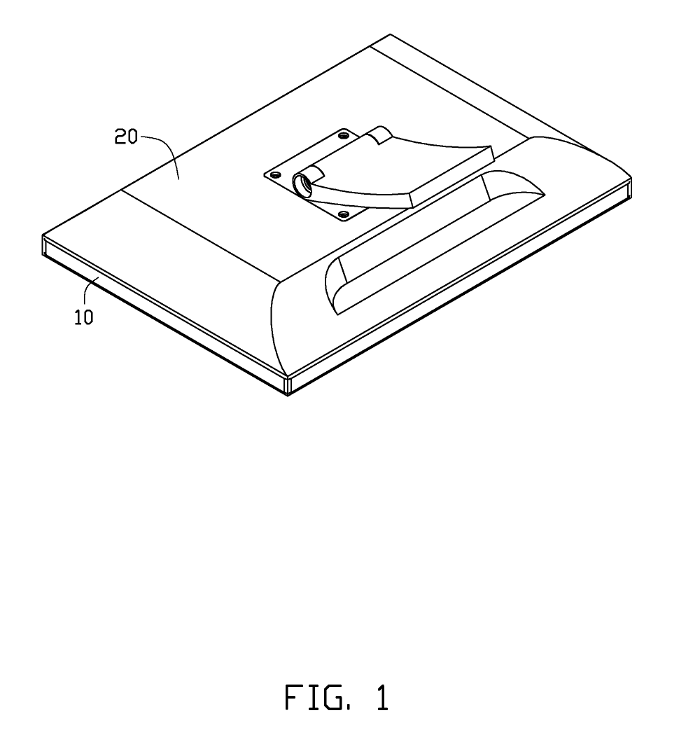

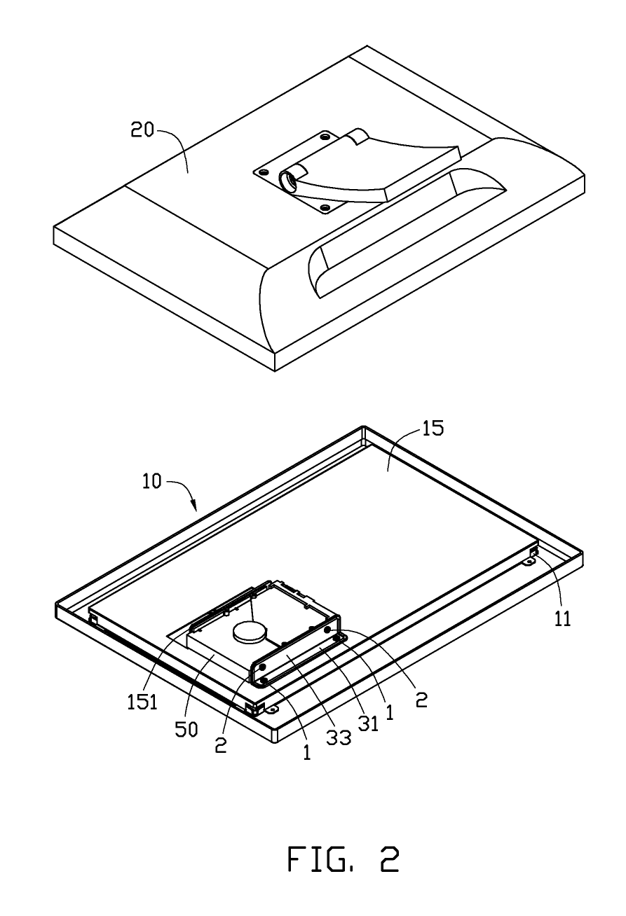

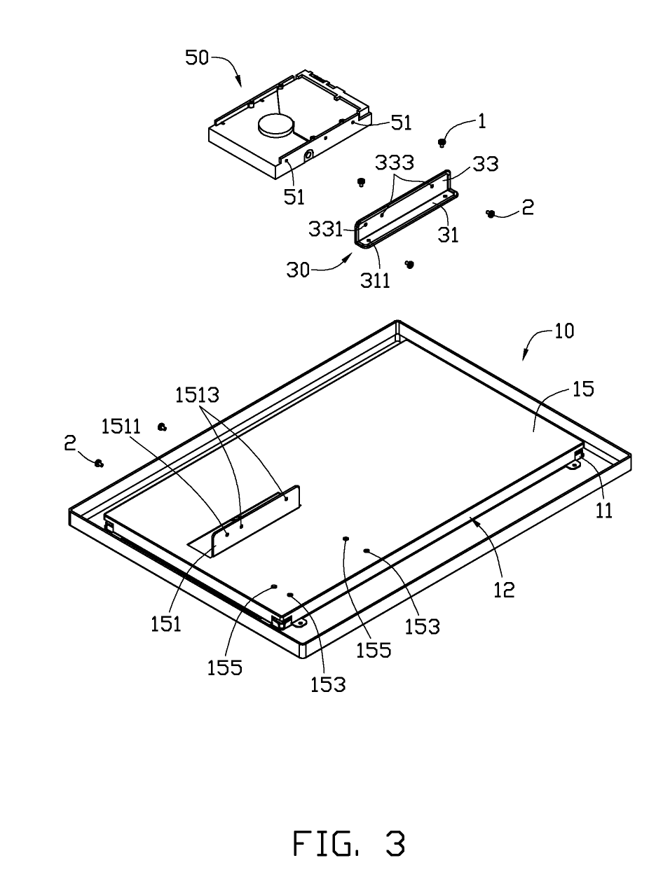

Referring to FIGS. 1-3, a disk drive mounting apparatus in accordance with an embodiment includes a mounting frame 10, a cover member 20, and a mounting member 30.

A display module 11 and a bracket 12 are mounted in the mounting frame 10. The display module 11 is received in the bracket 12. The bracket 12 includes a maintaining plate 15 substantially parallel to a top surface of the display module 11. In one embodiment, the mounting apparatus is a monitor of an all-in-one computer. An installing piece 151 extends from the maintaining plate 15. The maintaining plate 15 defines two first mounting holes 153 and two second mounting holes 155. A first line is defined by connecting the two first mounting holes 153, and a second line is defined by connecting the two second mounting holes 155. In one embodiment, the first line and the second line are substantially parallel to the installing piece 151. A distance between the first line and the installing piece 151 is larger than that between the second line and the installing piece 151. In one embodiment, the installing piece 151 is substantially perpendicular to the maintaining plate 15. The installing piece 151 defines a first installing hole 1511 and two second installing holes 1513. One of the two second installing holes 1513 is located between the first installing hole 1511 and the other of the two second installing holes 1513. In one embodiment, the installing piece 151 is integrated with the maintaining plate 15.

The mounting member 30 includes a mounting piece 31 and a limiting piece 33 connected to the mounting piece 31. The mounting piece 31 is substantially perpendicular to the limiting piece 33 and defines two securing holes 311. The limiting piece 33 defines a first limiting hole 331 and two second limiting holes 333. The first limiting hole 331 corresponds to the first installing hole 1511. The two second limiting holes 333 correspond to the two second installing holes 1513. In one embodiment, the limiting piece 33 is similar to the installing piece 151.

The mounting member 30 is capable of being secured to a first position and a second position in the maintaining plate 15.

When the mounting member 30 is secured to a first position, the mounting piece 31 abuts the maintaining plate 15, and each of the two securing holes 311 is aligned with each of the two first mounting holes 153. Two first locking members 1, such as screws, are locking into the two securing holes 311 and the first mounting holes 153 to secure the mounting member 30 to the first position in the maintaining plate 15. A first disk drive 50 can be secured between the installing piece 151 and the limiting piece 33. Each of two opposite sides of the first disk drive 50 defines two first locking holes 51. The two first locking holes 51 correspond to the first installing hole 1511 and the two second installing holes 1513. In one embodiment, the first disk drive 50 is a 3.5 inch hard disk drive.

In assembly, the first disk drive 50 is placed between the installing piece 151 and the limiting piece 33 and abuts the installing piece 151 and the limiting piece 33. The two first locking holes 51 are aligned with the first installing hole 1511, the other one of the two second installing holes 1513, the first limiting hole 331 and one of the two second limiting holes 333. The one of the two second limiting holes 333 corresponds to the other one of the two second installing holes 1513. One second locking member 2, such as screw, is locked into the first installing hole 1511 and a corresponding one of the two first locking holes 51. Another second locking member 2 is locked into the other one of the two second installing holes 1513 and a corresponding one of the two first locking holes 51. Another second locking member 2 is locked into the first limiting hole 331 and the corresponding one of the two first locking holes 51 to secure the first disk drive 50 between the installing piece 151 and the mounting member 30 in the first position.

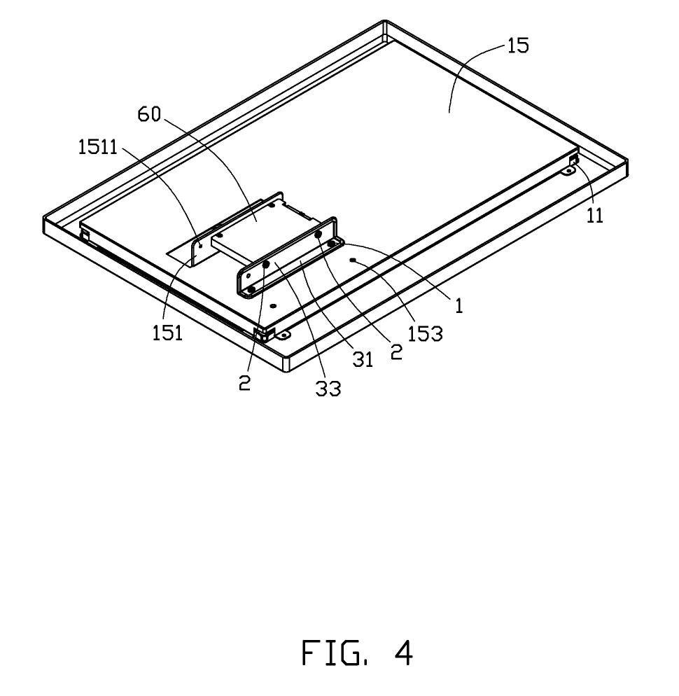

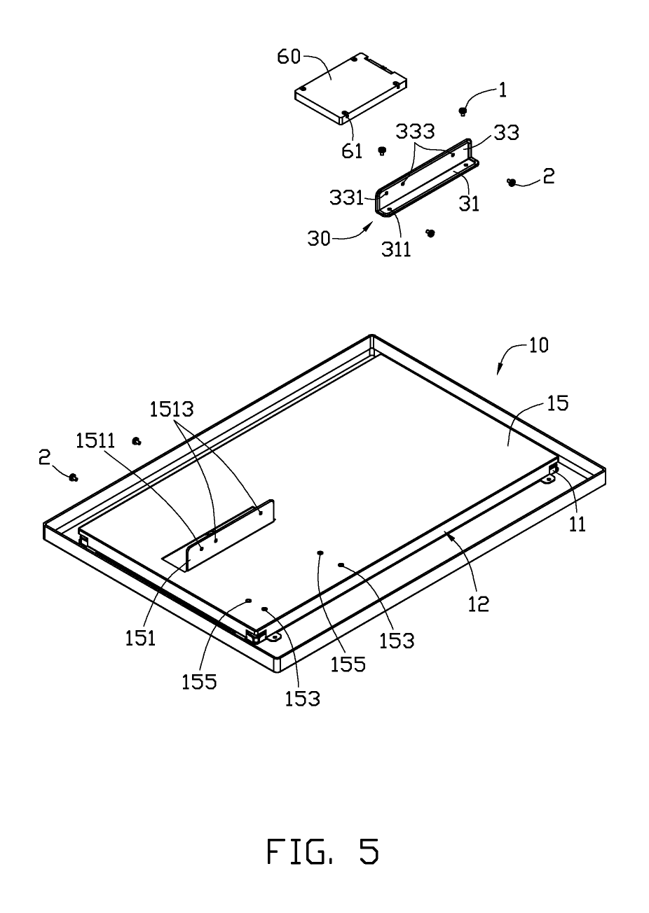

Referring to FIG. 4 and FIG. 5, when the mounting member 30 is secured in a second position, the mounting piece 31 abuts the maintaining plate 15, and each of the two securing holes 311 is aligned with each of the two second mounting holes 155. The two first locking members 1 are locking into the two securing holes 311 and the second mounting holes 155 to secure the mounting member 30 to the second position in the maintaining plate 15. A second disk drive 60 can be secured between the installing piece 151 and the limiting piece 33. Each of two opposite sides of the second disk drive 60 defines two second locking holes 61. The two second locking holes 61 correspond to the two second installing holes 1513. In one embodiment, the second disk drive 60 is a 2.5 inch hard disk drive.

In assembly, the second disk drive 60 is placed between the installing piece 151 and the limiting piece 33 and abuts the installing piece 151 and the limiting piece 33. The two second locking holes 61 are aligned with the two second installing holes 1513. The two second locking members 2 are locking into the two second installing holes 1513 and the two second locking holes 61, to secure the second disk drive 60 between the installing piece 151 and the mounting member 30 in the second position. The limiting piece 33 is substantially parallel to the installing piece 1151. A distance between the installing piece 151 and the limiting piece 33, when the mounting member 30 is in the first position, is larger than that between the installing piece 151 and the limiting piece 33, when the mounting member 30 is in the second position.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A disk drive mounting apparatus comprising:
a bracket comprising a maintaining plate and an installing piece extending from the maintaining plate; and
a mounting member comprising a limiting piece substantially parallel to the installing piece,
wherein the mounting member is secured to the maintaining plate in a first position or a second position; a distance between the installing piece and the limiting piece when the mounting member is in the first position, is larger than a distance between the installing piece and the limiting piece when the mounting member is in the second position, and
wherein when the mounting member is in the first position, the installing piece and the limiting piece are adapted to secure a first disk drive therebetween; and when the mounting member is in the second position, the installing piece and the limiting piece are adapted to secure a second disk drive of a size smaller than a size of the first disk drive.

2. The disk drive mounting apparatus of claim 1, wherein the bracket receives a display module, the installing piece is integrated with the maintaining plate.

3. The disk drive mounting apparatus of claim 1, wherein both the installing plate and the limiting piece are substantially perpendicular to the maintaining plate.

4. The disk drive mounting apparatus of claim 1, wherein the mounting member further comprises a mounting piece connected to the limiting piece, the mounting piece defines two securing holes, and the maintaining plate defines two first mounting holes and two second mounting holes; when the mounting member is in the first position, each of the two securing holes is aligned with each of the two first mounting holes; and when the mounting member is in the second position, each of the two securing holes is aligned with each of the two second mounting holes.

5. The disk drive mounting apparatus of claim 4, wherein a first line is defined by connecting the two first mounting holes, a second line is defined by connecting the two second mounting holes, and the first line and the second line are substantially parallel to the installing piece; and a distance between the first line and the installing piece is larger than a distance between the second line and the installing piece.

6. The disk drive mounting apparatus of claim 1, wherein the installing piece defines a first installing hole and two second installing holes, and the limiting piece defines a first limiting hole and two second limiting holes; and the first limiting hole is aligned to the first installing hole, and each of the two second limiting holes is aligned to each of the two second installing holes.

7. The disk drive mounting apparatus of claim 6, wherein one of the two second installing holes is located between the first installing hole and another one of the two second installing holes; and one of the two second limiting holes is located between the first limiting hole and another one of the two second limiting holes.

8. The disk drive mounting apparatus of claim 7, wherein the first installing hole and the other one of the two second installing holes are adapted to be aligned with two first locking holes of a first side of the first disk drive, and the first limiting hole and the other one of the two second limiting holes are adapted to be aligned with another two first locking holes of a second side of the first disk drive, which is opposite to the first side; and each of the two second installing holes and each of the two second limiting holes are configured to be aligned with each of two second locking holes of a second disk drive.

9. The disk drive mounting apparatus of claim 1, wherein the disk drive mounting apparatus is a monitor of an all-in-one computer.

10. A disk drive mounting apparatus comprising:
A bracket comprising a maintaining plate, an installing piece extending from the maintaining plate, and the maintaining plate defines two first mounting holes and two second mounting holes; and
a mounting member comprising a mounting piece abutting the maintaining plate, and the mounting piece defines two securing holes,
wherein the mounting member is secured to the maintaining plate in a first position by each of two securing members locking through each of the two securing holes and each of the two first mounting holes, each of the two securing holed is aligned with each of the two first mounting holes; or the mounting member is secured to the maintaining plate in a second position by each of two second locking members locking through each of the two securing holes and each of the two second mounting holes, each of the two securing holes is aligned with the each of the two second mounting holes, and
wherein a first line is defined by connecting the two first mounting holes, and a second line is defined by connecting the two second mounting holes; the first line and the second line are substantially parallel to the installing piece, and a distance between the first line and the installing piece is larger than a distance between the second line and the installing piece; when the mounting member is in the first position, the installing piece and the mounting member are adapted to secure a first disk drive therebetween; and when the mounting member is in the second position, the installing piece and the mounting member are adapted to secure a second disk drive of a size smaller than a size of the first disk drive.

11. The disk drive mounting apparatus of claim 10, wherein the mounting member further comprises a limiting piece connected to the mounting piece, the limiting piece is substantially parallel to the installing piece, and the limiting piece and the installing piece are adapted to secure the first disk drive and the second disk drive between therein.

12. The disk drive mounting apparatus of claim 11, wherein a distance between the installing piece and the limiting piece when the mounting member is in the first position, is larger than a distance between the installing piece and the limiting piece when the mounting member is in the second position.

13. The disk drive mounting apparatus of claim 10, wherein the bracket receives a display module, the installing piece is integrated with the maintaining plate.

14. The disk drive mounting apparatus of claim 11, wherein both the installing plate and the limiting piece are substantially perpendicular to the maintaining plate.

15. The disk drive mounting apparatus of claim 11, wherein the installing piece defines a first installing hole and two second installing holes, and the limiting piece defines a first limiting hole and two second limiting holes; and the first limiting hole is aligned to the first installing hole, and each of the two second limiting holes is aligned to each of the two second installing holes.

16. The disk drive mounting apparatus of claim 15, wherein first of the two second installing holes is located between the first installing hole and second of the two second installing holes; and first of the two second limiting holes is located between the first limiting hole and second of the two second limiting holes.

17. The disk drive mounting apparatus of claim 16, wherein the first installing hole and the second of the two second installing holes are adapted to be aligned with two first locking holes of a first side of the first disk drive, and the first limiting hole and the first of the two second limiting holes are adapted to be aligned with two first locking holes of a second side opposite to the first side of the first disk drive; and each of the two second installing holes and each of the two second limiting holes are configured to be aligned with each of two second locking holes of a second disk drive.

18. The disk drive mounting apparatus of claim 10, wherein the mounting apparatus is a monitor of an all-in-one computer.
